(19) United States
(12) Patent Application Publication
(10) Pub. No.: US 2026/0338840 A1
(43) Pub. Date: Oct. 29, 2026

(54) SYSTEM FOR MEASURING CURRENT

(71) Applicant: IRISS Holdings, Inc., Bradenton, FL (US)

(72) Inventors: Martin Robinson, Bradenton, FL (US); Luke Robinson, Bradenton, FL (US); Samir Kuliev, Sarasota, FL (US); Andriy Knyaz, Bradenton, FL (US)

(73) Assignee: IRISS Holdings, Inc., Bradenton, FL (US)

(21) Appl. No.: 19/659,678

(22) Filed: Apr. 27, 2026

Related U.S. Application Data
(60) Provisional application No. 63/795,513, filed on Apr. 27, 2025.

(51) Int. Cl. G01R 19/22; G01R 15/18; G01R 19/00; G01R 19/25

(52) U.S. Cl. CPC G01R 19/22; G01R 15/18; G01R 19/0053; G01R 19/0092; G01R 19/2506

(57) ABSTRACT

According to one example, a system for current measurement includes a body that can be attached to, or positioned in close proximity to, an electrical component. The system further includes an iron core coil, at least one precision diode, a signal integrator, and an amplifier, each of which are positioned at least partially in the body. The iron core coil can detect a magnetic field generated by current flow in the electrical component, and can generate an alternating current (AC) voltage based on the detected magnetic field. The precision diode(s) can receive the AC voltage and convert the received AC voltage to a pulsed direct current (DC) voltage. The signal integrator can receive the pulsed DC voltage and smooth one or more ripples in the received pulsed DC voltage. The amplifier can receive the smoothed DC voltage and amplify the smoothed DC voltage for current measurement.

### CROSS REFERENCE TO RELATED APPLICATIONS

This application claims priority to U.S. Provisional App. 63/795,513, titled “System for Measuring Current,” filed on Apr. 27, 2025. The entire contents of U.S. Provisional App. 63/795,513 are incorporated herein by reference.

### TECHNICAL FIELD

This disclosure relates generally to electrical systems, and more specifically to a system for measuring current of an electrical component.

### BACKGROUND

Traditional approaches to measuring current of an electrical component (such as a power distribution system, including, for example, a high-power transmission bar) include shunt resistors and magnetic loops. These traditional approaches, however, may be deficient.

### SUMMARY

According to one example, a system for current measurement includes a body that can be attached to an electrical component or that can be positioned in close proximity to the electrical component. The system further includes an iron core coil, at least one precision diode, a signal integrator, and an amplifier, each of which are positioned at least partially in the body. The iron core coil can detect a magnetic field generated by current flow in the electrical component, and can generate an alternating current (AC) voltage based on the detected magnetic field. The precision diode(s) can receive the AC voltage and convert the received AC voltage to a pulsed direct current (DC) voltage. The signal integrator can receive the pulsed DC voltage and smooth one or more ripples in the received pulsed DC voltage. The amplifier can receive the smoothed DC voltage and amplify the smoothed DC voltage for current measurement.

In one or more (e.g., all) of the above example(s), the system can further include at least one processor positioned at least partially within the body. The at least one processor can measure a current of the electrical component based on the amplified DC voltage.

In one or more of the above example(s), the system can further include a digital-to-analog converter (DAC) positioned at least partially within the body, and at least one processor positioned at least partially within the body. The DAC can process the amplified DC voltage for the current measurement. The at least one processor can measure a current of the electrical component based on the processed DC voltage.

In one or more of the above example(s), the electrical component is a high-power transmission bar.

In one or more of the above example(s), the at least one precision diode includes two precision diodes. In one or more of the above example(s), the at least one precision diode includes one precision diode.

In one or more of the above example(s), the body is a modular body that can be coupled to a second body. The second body includes at least one processor that can measure a current of the electrical component based on the amplified DC voltage, and a transmitter that can communicate the measured current of the electrical component.

In one or more of the above example(s), the system can further include a transmitter positioned at least partially within the body. The transmitter can communicate the measured current of the electrical component. In one or more of the above example(s), the transmitter includes a wireless transmitter that can wirelessly communicate the measured current to an external device. In one or more of the above example(s), the transmitter includes a wired transmitter that can communicate the measured current to an external device over a wired connection.

In one or more of the above example(s), the surface of the body can be coupled to a single side of the electrical component. In one or more of the above example(s), the surface of the body can be coupled to a structure that is in close proximity to the electrical component. In one or more of the above example(s), the surface of the body can be held by a user in close proximity to the electrical component.

According to another example, a method includes positioning an iron core coil at least partially within a body of a system for current measurement. The iron core coil can (i) detect a magnetic field generated by current flow in an electrical component, and (ii) generate an alternating current (AC) voltage based on the detected magnetic field. The method further includes positioning at least one precision diode at least partially within the body. The at least one precision diode can receive the AC voltage and convert the received AC voltage to a pulsed direct current (DC) voltage. The method further includes positioning a signal integrator at least partially within the body. The signal integrator can receive the pulsed DC voltage and smooth one or more ripples in the received pulsed DC voltage. The method further includes positioning an amplifier at least partially within the body. The amplifier can receive the smoothed DC voltage and amplify the smoothed DC voltage for current measurement. In some examples, the system for current measurement in the above example method can include any of the features / components of one or more of the above examples.

According to a further example, a method includes one of (i) coupling a body of a system for current measurement to an electrical component, or (ii) positioning the body in close proximity to the electrical component. The system for current measurement includes (a) an iron core coil positioned at least partially within the body, (b) at least one precision diode positioned at least partially within the body, (c) a signal integrator positioned at least partially within the body, (d) an amplifier positioned at least partially within the body, and (e) at least one processor positioned at least partially within the body. The method further includes receiving, via a user interface, a measurement of a current of the electrical component from the system for current measurement. In some examples, the system for current measurement in the above example method can include any of the features / components of one or more of the above examples.

### BRIEF DESCRIPTION OF THE FIGURES

For a more complete understanding of the present disclosure and one or more examples of the features and advantages of the present disclosure, reference is now made to the following description, taken in conjunction with the accompanying drawings, in which:

FIGS. 1A-1C illustrate an example system 10 for measuring current of an electrical component 100;

FIG. 2 illustrates an example of system 10 of FIGS. 1A-1B in the form of a modular device 50; and

FIG. 3 illustrates an example of a system 10 with a clip 110 for coupling the system 10 to an electrical component 100.

### DETAILED DESCRIPTION

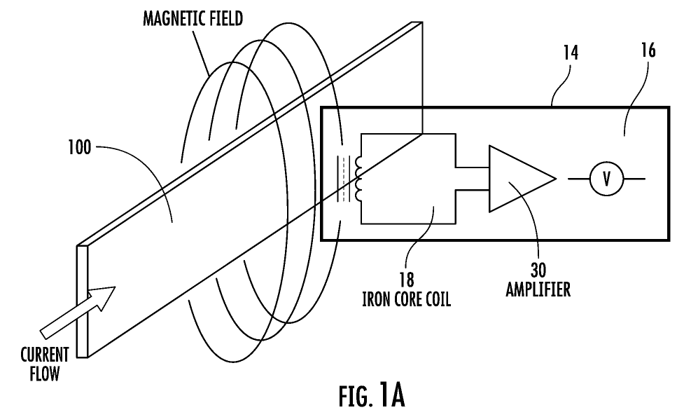

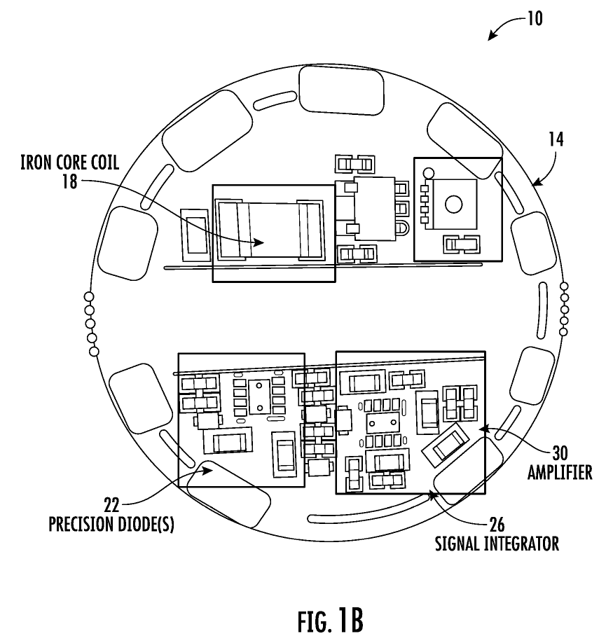

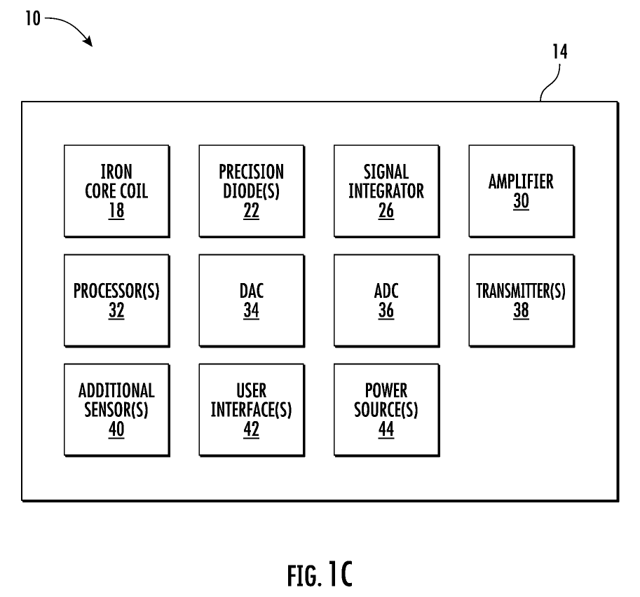

Examples in the present disclosure are best understood by referring to FIGS. 1A-3 of the drawings, like numerals being used for like and corresponding parts of the various drawings.

Traditional approaches to measuring current (e.g., current flow) of an electrical component (such as a power distribution system, including, for example, a high-power transmission bar) include shunt resistors and magnetic loops. These traditional approaches, however, may be deficient. As an example of this, to measure current, shunt resistors are positioned in direct contact with the conductor, which may be impractical (or may even be impossible) in many industrial settings. As another example, to measure current, magnetic loops are positioned to completely encircle the conductor, which also may be impractical (or may even be impossible) in many industrial settings.

In contrast to this, the system 10 of FIGS. 1A-3 may address one or more of these deficiencies. For example, the system 10 may include a body 14 that can be attached to (or otherwise coupled to, or positioned in close proximity to) an electrical component 100 (such as a high-power transmission bar), and may further include an iron core coil 18 (or other ferromagnetic coil) positioned at least partially in the body 14, and that can detect a magnetic field generated by current flow in the electrical component 100.

In some examples, the body 14 (with the iron core coil 18) is attached to an electrical component 100, thereby allowing the current (e.g., current flow) of the electrical component 100 to be measured. This may, in some examples, allow the current to be measured constantly (or periodically) without further user intervention (as the body 14 is attached to the electrical component 100, and may remain attached until it is removed).

In some examples, the body 14 (with the iron core coil 18) can be attached to a single side of the electrical component 100 (as opposed to surrounding all sides of the electrical component 100), thereby allowing the current of the electrical component 100 to be measured. In some examples, the body 14 (with the iron core coil 18) can be positioned in close proximity to the electrical component 100 (as opposed to being in direct contact with the electrical component 100), thereby allowing the current of the electrical component 100 to be measured. As such, in some examples, the system 10 allows for non-intrusive measurements from (i) one side of electrical component 100 and/or (ii) from close proximity to the electrical component 100, as opposed to the full encircling of the electrical component conductor that may be required by magnetic loops and also as opposed to the direct contact that may be required by shunt resistors. Furthermore, the system 10 may be more easily adapted to the different sizes and/or types of electrical components 100, as it may not require direct contact with or encircling of the electrical component 100, in some examples.

FIGS. 1A-1C illustrate an example system 10 for measuring current (e.g., current flow). In some examples, system 10 may measure current in an electrical component 100. The electrical component 100 may be any type of electrical component(s). In some examples, the electrical component 100 is (or is a part of, or includes) a power distribution system. As one example of this, the electrical component 100 is (or is a part of, or includes) a high-power transmission bar or cable(s), such as those used in various industrial and electrical applications. A high-power transmission bar is a conductive bar used in electrical systems to distribute large amounts of power, typically at high voltage. The high-power transmission bar is commonly used in high-voltage systems, such as those found in utility substations, power plants, and industrial settings. Furthermore, the high-power transmission bar is often referred to as a busbar. In the example illustrated in FIG. 1A, the electrical component 100 is a high-power transmission bar. However, in other examples, the electrical component 100 is (or is a part of, or includes) any other electrical component(s).

In the example illustrated in FIGS. 1A-1B, the system 10 includes a body 14, an iron core coil 18, a precision diode 22, a signal integrator 26, and an amplifier 30. In other examples, such as the example illustrated in FIG. 1C, the system 10 may include additional or less components, examples of which are discussed below.

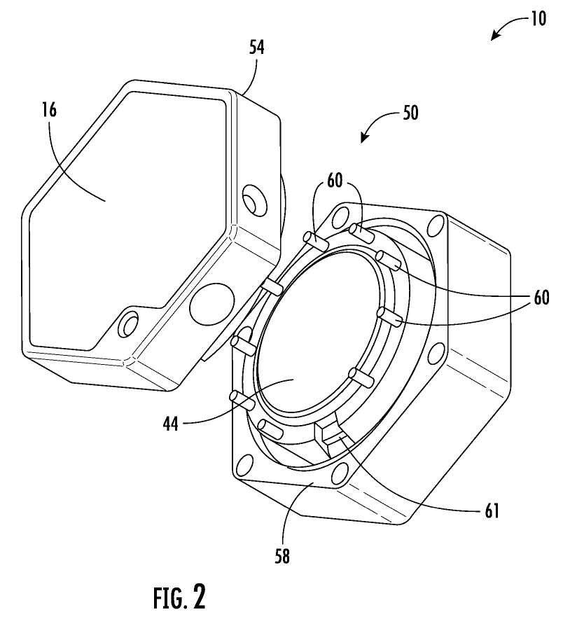

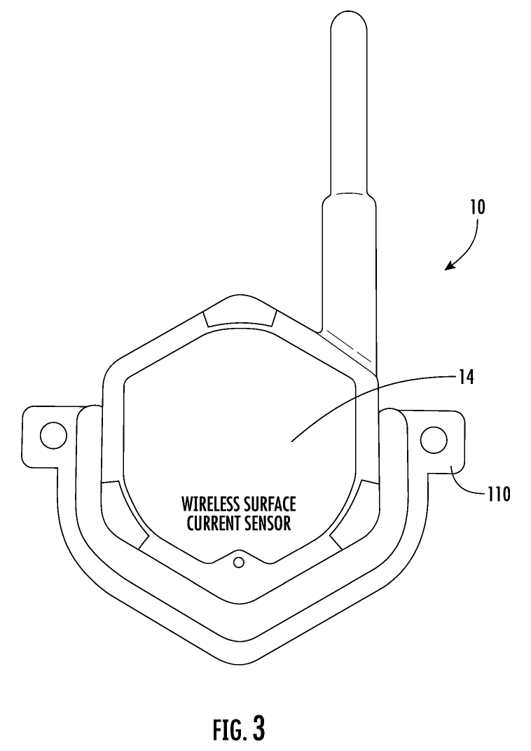

The body 14 is (or includes) a structure that holds one or more components of the system 10, in some examples. In some examples, the body 14 may at least partially encapsulate one or more of these components of system 10. The body 14 may be made of any material that can be used in measuring current, and may have any shape that can be used in measuring current. In the illustrated examples, the body 14 includes a back side 16 (not visible in FIG. 1B, but an example of which is illustrated in FIG. 2) that can be positioned on (or otherwise mounted on) the electrical component 100. The back side 16 (and/or the body 14) may be positioned on (or otherwise coupled to) the electrical component 100 in any manner that allows for current measurement. As examples of this, the back side 16 (and/or the body 14) may be positioned on (or otherwise coupled to) the electrical component 100 via (i) an adhesive (such as glue), (ii) one or more magnets, (iii) a strap, (iv) one or more screws, (v) one or more nuts and bolts, (vi) a clip (such as the clip 110 shown in FIG. 3, which can be coupled to the body 14 and may further be coupled to the electric component 100 (via one or more connectors, such as screws)), any other manner of positioning (or otherwise coupling) the back side 16 (and/or the body 14) to the electrical component 100, or (vii) any combination of the preceding.

In some examples, the body 14 is positioned on (or otherwise coupled to) a single side of the electrical component 100 (as opposed to having encircle the electrical component 100). In some examples, the body 14 is positioned in close proximity to (e.g., near) the electrical component 100 (e.g., near a single side of the electrical component 100), as opposed to being in direct contact with the electrical component 100. As one example of this, the body 14 is separated from the electrical component 100 by a distance that (i) causes the body 14 to not be in direct contact with the electrical component 100, and (ii) is sufficiently small to allow the iron core coil 18 to reliably sense the relevant electrical or electromagnetic characteristics of the electrical component 100. These examples allow the body 14 to be quickly and easily installed on the electrical component 100 (or in close proximity to the electrical component 100), without interrupting the power flow, in some examples.

In the example illustrated in FIGS. 1A-1C, the system 10 includes the iron core coil 18. The iron core coil 18 (which may also be referred to as an iron core inductor) is a structure, device, and/or component that, in some examples, (i) detects a magnetic field generated by current flow in the electrical component 100, and (ii) generates an alternating current (AC) voltage based on the detected magnetic field. In some examples, the iron core coil 18 includes a coil of wire (e.g., copper wire) that is wrapped around a core cylinder made of iron (e.g., the cylinder is solid iron, the iron is coated in a protected layer of insulating material). Although system 10 is described herein as including an iron core coil 18, in other examples, the system 10 includes any other ferromagnetic core coil that can be used in measuring current, and/or that can (i) detect a magnetic field generated by current flow in the electrical component 100, and (ii) generate an alternating current (AC) voltage based on the detected magnetic field.

As is discussed above, in some examples, the iron core coil 18 (i) detects a magnetic field generated by current flow in the electrical component 100, and (ii) generates an AC voltage based on the detected magnetic field. In some examples, the iron core coil 18 operates pursuant to Faraday’s Law of Induction, which states that a changing magnetic field can generate an electrical voltage in a nearby coil. In some examples, the iron core coil 18 is a highly sensitive magnetic field sensor capable of detecting the magnetic field generated by the current flow in the electrical component 100. In some examples, the AC voltage generated by the iron core coil 18 based on the detected magnetic field may match (or substantially match, e.g., +/- 10 percent) the strength of the current flow in the electrical component 100. As such, as is discussed above, this AC voltage may be used to measure the current in the electrical component 100.

In some examples, the iron core coil 18 can ensure precise measurements, even in high-power applications. For example, the iron core coil 18 can be used to accurately measure both small and very large currents (i.e., a wide range of currents) — from a few amperes to tens of thousands of amperes.

The iron core coil 18 is positioned at least partially within the body 14, in some examples. In some examples, the iron core coil 18 is positioned entirely within the body 14 (e.g., no portion of the iron core coil 18 extends out of the body 14). In other examples, the iron core coil 18 is only partially positioned within the body 14 (e.g., a portion of the iron core coil 18 may extend partially out of the body 14).

Any number of iron core coils 18 may be positioned at least partially in the body 14, in some examples. For example, only a single iron core coil 18 may be positioned at least partially in the body 14. As another example, more than one iron core coil 18 (e.g., two or more) may be positioned at least partially in the body 14. In the example illustrated in FIGS. 1A-1B, one iron core coil 18 is positioned at least partially in the body 14.

In the example illustrated in FIGS. 1A-1C, the system 10 includes the precision diode 22. The precision diode 22 is a structure, device, component, and/or circuit that, in some examples, (i) receives the AC voltage from the iron core coil 18, and (ii) converts the received AC voltage to a pulsed direct current (DC) voltage. In some examples, the precision diode 22 is (or includes) a circuit that mimics the behavior of an ideal diode (also referred to as a perfect diode) by compensating for voltage drop. As one example of this, the precision diode 22 is (or includes) a precision rectifier circuit that is configured to emulate ideal diode behavior by compensating for forward voltage drop. In some examples, the precision diode 22 can operate at low (or very low) voltages, which can make system 10 energy-efficient. Furthermore, although system 10 is described herein as including a precision diode 22, in other examples, the system 10 may instead include an ideal diode (or any other diode that can be used to accurately measure current), and/or that can (i) receive the AC voltage from the iron core coil 18, and (ii) convert the received AC voltage to a pulsed direct current (DC) voltage.

The precision diode 22 is positioned at least partially within the body 14, in some examples. In some examples, the precision diode 22 is positioned entirely within the body 14 (e.g., no portion of the precision diode 22 extends out of the body 14). In other examples, the precision diode 22 is only partially positioned within the body 14 (e.g., a portion of the precision diode 22 may extend partially out of the body 14).

Any number of precision diodes 22 may be positioned at least partially in the body 14, in some examples. For example, only a single precision diode 22 may be positioned at least partially in the body 14. As another example, more than one precision diode 22 (e.g., two or more) may be positioned at least partially in the body 14. In the example illustrated in FIG. 1B, two precision diodes 22 are positioned at least partially in the body 14. In some examples, the two precision diodes 22 create a differential input, which enhances the sensitivity and helps suppress noise, in some examples.

In the example illustrated in FIGS. 1A-1C, the system 10 includes the signal integrator 26. The signal integrator 26 is a structure, device, component, and/or circuit that, in some examples, (i) receives the pulsed DC voltage from the precision diode(s) 22, and (ii) smooths one or more ripples in the received pulsed DC voltage. In some examples, the signal integrator 26 smooths one or more ripples in the received pulsed DC voltage by, for example, averaging out the high-frequency variations (e.g., effectively acting as a low-pass filter). In some examples, the signal integrator 26 is (or includes) a signal integrator circuit that is configured to smooth the pulsed DC voltage by reducing ripple and high-frequency variations.

The signal integrator 26 is positioned at least partially within the body 14, in some examples. In some examples, the signal integrator 26 is positioned entirely within the body 14 (e.g., no portion of the signal integrator 26 extends out of the body 14). In other examples, the signal integrator 26 is only partially positioned within the body 14 (e.g., a portion of the signal integrator 26 may extend partially out of the body 14).

Any number of signal integrators 26 may be positioned at least partially in the body 14, in some examples. For example, only a single signal integrator 26 may be positioned at least partially in the body 14. As another example, more than one signal integrator 26 (e.g., two or more) may be positioned at least partially in the body 14. In the example illustrated in FIG. 1B, one signal integrator 26 is positioned at least partially in the body 14.

In the example illustrated in FIGS. 1A-1C, the system 10 includes the amplifier 30. The amplifier 30 is a structure, device, component, and/or circuit that, in some examples, (i) receives the smoothed DC voltage from the signal integrator 26, and (ii) amplifies (e.g., boosts) the smoothed DC voltage for current measurement. In some examples, the amplifier 30 amplifies the smoothed DC voltage to a level that can be read by a digital system (or an analog system), for example. In some examples, the amplifier 30 is (or includes) an amplifier circuit that is configured to amplify the smoothed DC voltage to a level suitable for measurement by a digital or analog system.

The amplifier 30 is positioned at least partially within the body 14, in some examples. In some examples, the amplifier 30 is positioned entirely within the body 14 (e.g., no portion of the amplifier 30 extends out of the body 14). In other examples, the amplifier 30 is only partially positioned within the body 14 (e.g., a portion of the amplifier 30 may extend partially out of the body 14).

Any number of amplifiers 30 may be positioned at least partially in the body 14, in some examples. For example, only a single amplifier 30 may be positioned at least partially in the body 14. As another example, more than one amplifier 30 (e.g., two or more) may be positioned at least partially in the body 14. In the example illustrated in FIG. 1B, one amplifier 30 is positioned at least partially in the body 14.

In some examples, as is illustrated in FIG. 1C, the system 10 also optionally includes one or more additional components for measuring current. As an example of this, the system 10 also includes, in some examples, one or more of (i) a processor 32, (ii) a digital-to-analog converter (DAC) 34, (iii) an analog-to-digital converter (ADC) 36, (iv) a transmitter 38, (v) an additional sensor 40, (vi) a user interface 42, (vii) a power source 44, (viii) any other component for measuring current, or (ix) any combination of the preceding.

The processor 32 is a structure, device, component, and/or circuit that, in some examples, (i) receives the amplified DC voltage (e.g., from the amplifier 30, from the DAC 34, from the ADC 36), and (ii) measures the current (e.g., current flow) of the electrical component 100 based on the amplified DC voltage. In some examples, the processor 32 is a processing unit that can process the signals from the iron core coil 18 (and/or other component(s) of the system 10), thereby allowing for the conversion of the detected magnetic field into a corresponding current measurement. In some examples, the processor 32 is (or is a part of, or includes) a central processing unit (CPU) that can measure current, any other computing device or computing component(s) that can measure current, or any combination of the preceding.

In addition to measuring the current (e.g., current flow) of the electrical component 100 based on the amplified DC voltage, in some examples, the processor 32 may communicate the measured current to another component, such as the transmitter 38 or the user interface 42 (discussed below).

The processor 32 is positioned at least partially within the body 14, in some examples. In some examples, the processor 32 is positioned entirely within the body 14 (e.g., no portion of the processor 32 extends out of the body 14). In other examples, the processor 32 is only partially positioned within the body 14 (e.g., a portion of the processor 32 may extend partially out of the body 14).

Any number of processors 32 may be positioned at least partially in the body 14, in some examples. For example, only a single processor 32 may be positioned at least partially in the body 14. As another example, more than one processor 32 (e.g., two or more) may be positioned at least partially in the body 14.

Although FIG. 1C illustrates the system 10 (and body 14) as optionally including the one or more processors 32, in some examples, the system 10 (and the body 14) may not include the one or more processors 32. In such examples, one or more signals representing the current (e.g., from the iron core coil 18, precision diodes(s) 22, signal integrator 26, and/or amplifier 30) may be communicated (e.g., via one or more transmitters 38) to an external device that includes the one or more processors 32. Then, the one or more processors 32 in the external device can measure the current (e.g., current flow) of the electrical component 100 based on the received signals.

In some examples, the system 10 also includes the DAC 34. The DAC 34 is a structure, device, component, and/or circuit that, in some examples, (i) receives the amplified DC voltage (e.g., from the amplifier 30) and (ii) processes the amplified DC voltage for current measurement. The DAC 34 may process the amplified DC voltage in any manner. As one example of this, the DAC 34 may process the amplified DC voltage by converting the amplified DC voltage to an analog signal. In some examples, the DAC 34 may then communicate the processed amplified DC voltage for current measurement (e.g., communicate the analog signal to the processor 32, communicate the analog signal to the transmitter 38).

The DAC 34 is positioned at least partially within the body 14, in some examples. In some examples, the DAC 34 is positioned entirely within the body 14 (e.g., no portion of the DAC 34 extends out of the body 14). In other examples, the DAC 34 is only partially positioned within the body 14 (e.g., a portion of the DAC 34 may extend partially out of the body 14).

Any number of DACs 34 may be positioned at least partially in the body 14, in some examples. For example, only a single DAC 34 may be positioned at least partially in the body 14. As another example, more than one DAC 34 (e.g., two or more) may be positioned at least partially in the body 14.

In some examples, the system 10 also includes the ADC 36 (or alternatively includes the ADC 36 instead of the DAC 34). The ADC 36 is a structure, device, component, and/or circuit that, in some examples, (i) receives the amplified DC voltage (e.g., from the amplifier 30) and (ii) processes the amplified DC voltage for current measurement. The ADC 36 may process the amplified DC voltage in any manner. As one example of this, the ADC 36 may process the amplified DC voltage by converting the amplified DC voltage to a digital signal (e.g., a digital representation of current). In some examples, the ADC 36 may then communicate the processed amplified DC voltage for current measurement (e.g., communicate the digital signal to the processor 32, communicate the digital signal to the transmitter 38).

The ADC 36 is positioned at least partially within the body 14, in some examples. In some examples, the ADC 36 is positioned entirely within the body 14 (e.g., no portion of the ADC 36 extends out of the body 14). In other examples, the ADC 36 is only partially positioned within the body 14 (e.g., a portion of the ADC 36 may extend partially out of the body 14).

Any number of ADCs 36 may be positioned at least partially in the body 14, in some examples. For example, only a single ADC 36 may be positioned at least partially in the body 14. As another example, more than one ADC 36 (e.g., two or more) may be positioned at least partially in the body 14.

In some examples, the system 10 also includes the transmitter 38. The transmitter 38 is a structure, device, component, and/or circuit that, in some examples, (i) receives the measured current or other signal (e.g., from the processor 32, from the DAC 34, from the ADC 36), and (ii) communicates the measured current or other signal (e.g., to an external device).

In some examples, the transmitter 38 is (or includes) a wireless transmitter that wirelessly communicates the measured current (e.g., to an external device). As one example of this, the transmitter 38 is (or includes) a BLUETOOTH transmitter that communicates the measured current or other signal (e.g., to an external device) via BLUETOOTH. As another example of this, the transmitter 38 is (or includes) a WIFI transmitter that communicates the measured current or other signal (e.g., to an external device) via WIFI. As another example of this, the transmitter 38 is (or includes) a radio transmitter that communicates the measured current or other signal (e.g., to an external device) via radio waves. As a further example, the transmitter 38 is (or includes) a near field communication (NFC) transmitter/tag that communicates the measured current or other signal (e.g., to an external device) via NFC. Examples of NFC communication are disclosed in U.S. Patent Application No. 18/388,793, entitled “Near Field Communication (NFC)-Based Asset Management System and Method”, and filed Nov. 10, 2023, the contents of which are hereby incorporated herein by reference in its entirety. In other examples, the transmitter 38 is (or includes) (i) any other transmitter that communicates via any other wireless protocol or standard, or (ii) any combination of the preceding.

In some examples, the transmitter 38 is (or includes) a wired transmitter that communicates the measured signal or other signal (e.g., to an external device) over a wired connection. In such examples, the wired transmitter communicates the measured signal or other signal (e.g., to an external device) over a physical medium, such as one or more cables or wires. Examples of such a physical medium include a Universal Serial Bus (USB) (such as, for example, a USB-A, USB-B, USB-C, Micro-USB, and Mini-USB), a twisted pair cable, a coaxial cable, a fibre optic cable, any other cable(s) or wire(s), any other physical medium for data communication, or any combination of the preceding. In examples where a wired transmitter is positioned at least partially in the body 14 (as is discussed below), the body 14 includes a port, socket, or other connector to allow the physical medium (e.g., a wire or cable) to be plugged into the wired transmitter in the body 14.

The transmitter 38 is positioned at least partially within the body 14, in some examples. In some examples, the transmitter 38 is positioned entirely within the body 14 (e.g., no portion of the transmitter 38 extends out of the body 14). In other examples, the transmitter 38 is only partially positioned within the body 14 (e.g., a portion of the transmitter 38 may extend partially out of the body 14).

Any number of transmitters 38 may be positioned at least partially in the body 14, in some examples. For example, only a single transmitter 38 may be positioned at least partially in the body 14. As another example, more than one transmitter 38 (e.g., two or more) may be positioned at least partially in the body 14. In examples where the body 14 includes multiple types of transmitters 38, each transmitter 38 may be the same type of transmitter (e.g., each transmitter 38 may be a wireless transmitter, each transmitter 38 may be a BLUETOOTH transmitter) or one or more (e.g., all) of the transmitters 38 may be different types of transmitters (e.g., one BLUETOOTH transmitter, one NFC transmitter/tag, and one wired transmitter)

In some examples, the transmitter 38 communicates the measured current or other signal to an external device. The external device is (or is a part of, or includes) any device that is separate from the body 14 (and/or the system 10), and that can receive the measured current or other signal from the transmitter 38, in some examples. As examples of this, the external device is (or is a part of, or includes) any computing device or system that receives data, stores data, transmits data, presents data for display to a user, and/or receives data input by a user, such as, for example, a personal computer, a server, a laptop, a computer tablet, an IPAD, a mobile telephone (such as a Smartphone), an electronic notebook, a personal digital assistant, any other computing device or system, any other processing device that can receive data, store data, transmit data, present data for display to a user, and/or receive data input by a user, or any combination of the preceding.

In some examples, the system 10 also includes the additional sensor 40. The additional sensor 40 is a structure, device, component, and/or circuit that, in some examples, senses, detects, and/or measures a stimuli and/or physical quantity. The additional sensor 40 may be any type of sensor. Examples of the additional sensor 40 include a temperature sensor (e.g., surface temperature), humidity sensor, ultrasound sensor, ultraviolet sensor, voltage sensor, smoke sensor, any other sensor, or any combination of the preceding. In some examples, by including the additional sensor 40, the system 10 may be able to both (i) measure the current flow of the electrical component 100, and (ii) sense, detect, and/or measure any other stimuli and/or physical quantity associated with the electrical component 100 (e.g., surface temperature of the electrical component). Additionally, the system 10 may also be able to communicate the sensed/detected/measured stimuli and/or physical quantity (e.g., via the transmitter 38, via the user interface 42).

The additional sensor 40 is positioned at least partially within the body 14, in some examples. In some examples, the additional sensor 40 is positioned entirely within the body 14 (e.g., no portion of the additional sensor 40 extends out of the body 14). In other examples, the additional sensor 40 is only partially positioned within the body 14 (e.g., a portion of the additional sensor 40 may extend partially out of the body 14).

Any number of additional sensors 40 may be positioned at least partially in the body 14, in some examples. For example, only a single additional sensor 40 may be positioned at least partially in the body 14. As another example, more than one additional sensor 40 (e.g., two or more) may be positioned at least partially in the body 14. In examples where the system 10 includes multiple sensors 40, each additional sensor 40 may be the same type of sensor (e.g., each additional sensor 40 may be a surface temperature sensor) or one or more (e.g., all) of the additional sensors 40 may be different types of sensor (e.g., one surface temperature sensor, one humidity sensor, and one ultrasound sensor).

In some examples, the system 10 also includes the user interface 42. The user interface 42 is a structure, device, component, and/or circuit that, in some examples, communicates with a user of the system 10. Examples of a user interface 42 include a display (e.g. a light emitting diode (LED) display, a liquid crystal display (LCD), any other visual display), an audio emitter (e.g., a speaker, a horn), a light (e.g., one or more LEDs), any other user interface that can communicate with a user, or any combination of the preceding. In some examples, the user interface 42 communicates with the user of the system 10 to communicate the measured current to the user. As examples of this, the user interface 42 may (i) provide a graphical display of the measured current on a display, (ii) provide an audio emission of the measured current (e.g., sounds may be emitted from a speaker that tell the user what the measured current is), (iii) provide a light output (e.g., flashing lights) that indicate the measured current (e.g., red flashing lights that warn the user that the current is too high), (iv) provide any other signal to the user; or (v) any combination of the preceding. In some examples, the user interface 42 can communicate any other information to the user (e.g., information from the additional sensor(s) 40, if any).

The user interface 42 is positioned at least partially within the body 14, in some examples. In some examples, the user interface 42 is positioned entirely within the body 14 (e.g., no portion of the user interface 42 extends out of the body 14). In other examples, the user interface 42 is only partially positioned within the body 14 (e.g., a portion of the user interface 42 may extend partially out of the body 14).

Any number of user interfaces 42 may be positioned at least partially in the body 14, in some examples. For example, only a single user interface 42 may be positioned at least partially in the body 14. As another example, more than one user interfaces 42 (e.g., two or more) may be positioned at least partially in the body 14. In examples where the system 10 includes multiple user interfaces 42, each user interface 42 may be the same type of user interface (e.g., each user interface 42 may be a display or a light output) or one or more (e.g., all) of the user interfaces 42 may be different types of user interfaces (e.g., one display, one audio emitter, and one light output).

In some examples, the system 10 also includes the power source 44. The power source 44 is a structure, device, and/or component that, in some examples, provides power to one or more of the components of system 10. Examples of a power source 44 include a battery (e.g., a rechargeable battery, a disposable battery), a power cord (e.g., for plugging into an outlet), a solar power source, any other power source, or any combination of the preceding.

The power source 44 is positioned at least partially within the body 14, in some examples. In some examples, the power source 44 is positioned entirely within the body 14 (e.g., no portion of the power source 44 extends out of the body 14). In other examples, the power source 44 is only partially positioned within the body 14 (e.g., a portion of the power source 44 may extend partially out of the body 14).

Any number of power sources 44 may be positioned at least partially in the body 14, in some examples. For example, only a single power source 44 may be positioned at least partially in the body 14. As another example, more than one power sources 44 (e.g., two or more) may be positioned at least partially in the body 14. In examples where the system 10 includes multiple power sources 44, each power source 44 may be the same type of power source (e.g., each power source 44 may be a battery) or one or more (e.g., all) of the power sources 44 may be different types of power source (e.g., one battery and one power cord).

In some examples, the system 10 (and/or the body 14) may be in the form of a standalone device that holds all of the components (or all of the needed components for measuring current) discussed above, thereby allowing the standalone device to measure the current on its own. In other examples, as is discussed below, the system 10 (and/or the body 14) may be in the form of a modular device that can be attached to other modular devices in order to measure the current (or otherwise operate).

Modifications, additions, or omissions may be made to system 10 of FIGS. 1A-1C without departing from the scope of the disclosure. For example, system 10 may include any number of components, such as processors, illustrated or described above. Also, any suitable logic may perform the functions of system 10 and the components and/or devices within system 10. Furthermore, one or more components of system 10 may be separated, combined, and/or eliminated.

In an example of operation of system 10, the body 14 is mounted on (or positioned on or otherwise coupled to) one side of the electrical component 100 (as is illustrated in FIG. 1A). In some examples, the body 14 is mounted in a location where a secure mount can be obtained, and where the position is free from significant external magnetic interference. Furthermore, while the body 14 may be mounted on (or positioned on or otherwise coupled to) the electrical component 100, in some examples, the body 14 may alternatively be mounted on (or positioned on or otherwise coupled to), or even held in (such as held manually by a user) a location that is close to the electrical component 100 (but not in direct contact with the electrical component 100, i.e., the body 14 does not actually touch the electrical component 100).

As current flows through the electrical component 100 (e.g., through a high-power transmission bar), a magnetic field is generated. When positioned on (or close) to the electrical component 100, the system 10 (via, for example, the iron core coil 18) can detect this magnetic field. The processor 32 (and/or other components of the system 10) can receive the data associated with the detected magnetic field (e.g., the voltage discussed above), and then convert this data into a current measurement. In some example, this conversion is based on the known relationship between the magnetic field strength and the current flow.

In some examples, the current measurement can be communicated, as is discussed above. For example, the current measurement is presented to a user via a user interface 42 of the body 14. Additionally or alternatively, the current measurement is communicated via a transmitter 38 (e.g., a wireless transmitter, a wired transmitter). In some examples, this communication is in the form of an analog signal or a digital signal. Additionally, in some examples, the communicated signal can be received by an external device (e.g., a mobile phone), and it can then be further processed and/or presented to a user (via a display). In some examples, the communicated signal (i.e., the measured current) can be integrated into existing monitoring systems, providing valuable data for managing and controlling high-power electrical systems.

In some examples, the system 10 may allow for continuous monitoring of the current flow of the electronic component 100, providing for real-time measurements. In other examples, the system 10 may allow for periodic monitoring of the current flow of the electronic component 100. In other examples, the system 10 may allow for on-demand monitoring of the current flow of the electronic component 100 (e.g., when a user utilizes a mobile phone or other device, to request that a measurement be performed).

In some examples, the system 10 may be calibrated prior to being used to measure unknown current flows, so as to ensure accuracy. Such calibration may involve running a known current through an electrical component 100 and adjusting the settings of the system 10 to match the known current value.

As is discussed below, in some examples, the system 10 (and/or the body 14) is in the form of a modular device that can be attached to other modular devices to measure the current (or otherwise operate). FIG. 2 illustrates an example of system 10 in the form of a modular device 50. In the example illustrated in FIG. 2, the modular device 50 includes a switchable sensor module 54 and a base module 58.

The switchable sensor module 54 is an example of the body 14 and one or more of the components discussed above. As such, in some examples, the switchable sensor module 54 includes the body 14, the back side 16, the iron core coil 18, the precision diode(s) 22, the signal integrator 26, the amplifier 30, and the DAC 34 (or ADC 36), if any, as is discussed above with regard to FIGS. 1A-1C (but is not explicitly shown in FIG. 2). In some examples, this allows the switchable sensor module 54 to be used to measure current of an electrical component 100, as is discussed above with regard to FIGS. 1A-1C. Furthermore, in some examples, the switchable sensor module 54 further includes an additional sensor 40, such as, for example, a surface temperature sensor. As such, in some examples, this allows the switchable sensor module 54 to be used to measure current and surface temperature of an electrical component 100.

The base module 58 is a second module (with a body and one or more components) to which the switchable sensor module 54 is coupled to (or otherwise attached to). When coupled together, the switchable sensor module 54 and the base module 58 may include one or more (e.g., all) of the functions discussed above with regard to regard to FIGS. 1A-1C. As an example of this, when coupled together (and when positioned on or near an electrical component 100), the switchable sensor module 54 and the base module 58 may measure the current (e.g., current flow) of the electrical component 100, and may further communicate the measured current to a user (via a user interface 42, and/or via one or more transmitters 38 (e.g., a NFC transmitter) that communicate the measured current to an external device to be displayed to the user, for example).

In some examples, the base module 58 includes any of the components that are not included in the switchable sensor module 54. As an example of this, the base module 58, in some examples, includes one or more of (i) a power source 44 (e.g., a battery, such as a 1 Amp coin cell battery) that can power the components of one or more (or both) the base module 58 and the switchable sensor module 54, (ii) one or more transmitters 38 (discussed above), (iii) one or more processors 32 (discussed above), (iv) a user interface 42 (discussed above), (v) connectors 60 (e.g., barrel connectors with pogo-pins to provide power and/or communication throughout the various modules), (vi) a positioning key 61 to assist in properly aligning the modules 54 and 58 when attaching them, (vii) one or more additional sensors 40 (examples of which are discussed above, such as sensors for measuring ambient temperature and/or ambient humidity), (viii) any other component(s), or any combination of the preceding.

In some examples, any of the switchable sensor module 54 and/or the base module 58 may include any of the other components discussed above. In other examples, any of the switchable sensor module 54 and/or the base module 58 may include any of the components discussed above, except for the components used to detect the magnetic field (e.g., the iron core coil 18, for example) – which are included in the switchable sensor module 54. For example, the switchable sensor module 54 may also include the power source 44 and/or the processor 32.

As is discussed above, the system 10 is a modular device 50. In some examples, this allows the switchable sensor module 54 to be attached to the base module 58 in order to perform the functions discussed above. However, in some examples, the switchable sensor module 54 may also be switched out with a different switchable sensor module 54. This different switchable sensor module 54 can include different sensor(s), which allows it to measure different stimuli and/or physical quantities. As examples of this, (i) a first switchable sensor module 54 includes sensor(s) that allow it to measure current (as is discussed above) and surface temperature, (ii) a second switchable sensor module 54 includes sensor(s) that allow it to measure internal temperature and/or internal humidity, (iii) a third switchable sensor module 54 includes sensor(s) that allow it to measure impact activity, (iv) a fourth switchable sensor module 54 includes sensor(s) that allow it to measure surface temperature, and (v) a fifth switchable sensor module 54 includes sensor(s) that allow it to measure internal temperature, internal humidity, and ultrasound. Any of these example switchable sensor modules 54 can be coupled to the base module 58, and each of these switchable sensor modules 54 can be removed from the base module 58 and replaced with any of the other switchable sensor modules 54, in some examples. In some examples, this allows the user to change out what sensors are used in the system 10 at any time. For example, if a current measurement is needed, a switchable sensor module 54 with current measuring components (e.g., an iron core coil 18) may be attached to the base module 58. Then, when a humidity measurement is needed, the switchable sensor module 54 with current measuring components can be removed, and replaced with a switchable sensor module 54 with a humidity sensor. Additionally, if one switchable sensor module 54 (e.g., for measuring current) breaks or malfunctions, it can be easily replaced with a new switchable sensor module 54 of the same type (e.g., for measuring current).

FIG. 3 illustrates an example of a system 10 with a clip 110 for coupling the system 10 to an electrical component 100. The system 10 and/or the electrical component 100 of FIG. 3 can be any one or more of the example systems 10 and/or electrical components 100 discussed herein. In the example illustrated in FIG. 3, the system 10 is (or includes) a wireless surface current sensor. In other examples, the system 10 of FIG. 3 is (or includes) a wireless surface temperature sensor, a wireless surface current / temperature sensor, any other sensor discussed herein, or any combination of the preceding. In the example illustrated in FIG. 3, the clip 110 is used to position the system 10 (e.g., the back side 16 and/or the body 14 of the system 10) on (or otherwise couple the system 10 to) the electrical component 100. In some examples, the clip 110 can be coupled to the body 14 (via one or more connectors, such as screws), and the clip 110 can be further coupled to the electrical component 100 (via one or more connectors, such as screws).

This specification has been written with reference to various non-limiting and non-exhaustive examples. However, it will be recognized by persons having ordinary skill in the art that various substitutions, modifications, or combinations of any of the disclosed examples (or portions thereof) may be made within the scope of this specification. Thus, it is contemplated and understood that this specification supports additional examples not expressly set forth in this specification. Such examples may be obtained, for example, by combining, modifying, or reorganizing any of the disclosed components, elements, features, aspects, characteristics, limitations, and the like, of the various non-limiting and non-exhaustive examples described in this specification. In this manner, Applicant reserves the right to amend the claims during prosecution to add features as variously described in this specification.

What is claimed is:

1. A system for current measurement, comprising:
a body having a surface configured to be: (i) coupled to an electrical component, or (ii) positioned in close proximity to the electrical component;
an iron core coil positioned at least partially within the body, the iron core coil configured to (i) detect a magnetic field generated by current flow in the electrical component, and (ii) generate an alternating current (AC) voltage based on the detected magnetic field;
at least one precision diode positioned at least partially within the body, the at least one precision diode configured to receive the AC voltage and convert the received AC voltage to a pulsed direct current (DC) voltage;
a signal integrator positioned at least partially within the body, the signal integrator configured to receive the pulsed DC voltage and smooth one or more ripples in the received pulsed DC voltage; and
an amplifier positioned at least partially within the body, the amplifier configured to receive the smoothed DC voltage and amplify the smoothed DC voltage for current measurement.

2. The system of claim 1, further comprising:
at least one processor positioned at least partially within the body, the at least one processor configured to measure a current of the electrical component based on the amplified DC voltage.

3. The system of claim 2, further comprising:
a transmitter positioned at least partially within the body, the transmitter configured to communicate the measured current of the electrical component.

4. The system of claim 3, wherein the transmitter comprises a wireless transmitter configured to wirelessly communicate the measured current to an external device.

5. The system of claim 3, wherein the transmitter comprises a wired transmitter configured to communicate the measured current to an external device over a wired connection.

6. The system of claim 1, further comprising:
an analog-to-digital converter (ADC) positioned at least partially within the body, the ADC configured to process the amplified DC voltage for the current measurement; and
at least one processor positioned at least partially within the body, the at least one processor configured to measure a current of the electrical component based on the processed DC voltage.

7. The system of claim 6, further comprising:
a transmitter positioned at least partially within the body, the transmitter configured to communicate the measured current of the electrical component.

8. The system of claim 7, wherein the transmitter comprises a wireless transmitter configured to wirelessly communicate the measured current to an external device.

9. The system of claim 7, wherein the transmitter comprises a wired transmitter configured to communicate the measured current to an external device over a wired connection.

10. The system of claim 1, wherein the electrical component is a high-power transmission bar.

11. The system of claim 1, wherein the at least one precision diode comprises two precision diodes.

12. The system of claim 1, wherein the at least one precision diode comprises one precision diode.

13. The system of claim 1, wherein the body is a modular body configured to be coupled to a second body, wherein the second body comprises:
at least one processor configured to measure a current of the electrical component based on the amplified DC voltage; and
a transmitter configured to communicate the measured current of the electrical component.

14. The system of claim 13, wherein the transmitter comprises a wireless transmitter configured to wirelessly communicate the measured current to a device external to the body and the second body.

15. The system of claim 13, wherein the transmitter comprises a wired transmitter configured to communicate the measured current to a device external to the body and the second body.

16. The system of claim 1, wherein the surface of the body is configured to be coupled to a single side of the electrical component.

17. The system of claim 1, wherein the surface of the body is configured to be coupled to a structure that is in close proximity to the electrical component.

18. The system of claim 1, wherein the surface of the body is configured to be held by a user in close proximity to the electrical component.

19. A method, comprising:
positioning an iron core coil at least partially within a body of a system for current measurement, the iron core coil configured to (i) detect a magnetic field generated by current flow in an electrical component, and (ii) generate an alternating current (AC) voltage based on the detected magnetic field;
positioning at least one precision diode at least partially within the body, the at least one precision diode configured to receive the AC voltage and convert the received AC voltage to a pulsed direct current (DC) voltage;
positioning a signal integrator at least partially within the body, the signal integrator configured to receive the pulsed DC voltage and smooth one or more ripples in the received pulsed DC voltage; and
positioning an amplifier at least partially within the body, the amplifier configured to receive the smoothed DC voltage and amplify the smoothed DC voltage for current measurement.

20. A method, comprising:
one of (i) coupling a body of a system for current measurement to an electrical component, or (ii) positioning the body in close proximity to the electrical component, wherein the system for current measurement comprises:
an iron core coil positioned at least partially within the body;
at least one precision diode positioned at least partially within the body;
a signal integrator positioned at least partially within the body;
an amplifier positioned at least partially within the body; and
at least one processor positioned at least partially within the body; and
receiving, via a user interface, a measurement of a current of the electrical component from the system for current measurement.
